(19) United States
(12) Patent Application Publication
(10) Pub. No.: US 2013/0306758 A1
(43) Pub. Date: Nov. 21, 2013

(54) PRECURSOR DISTRIBUTION FEATURES FOR IMPROVED DEPOSITION UNIFORMITY

(71) Applicant: Applied Materials, Inc., (US)

(72) Inventors: Soonam Park, Sunnyvale, CA (US); Kimberly Hinkley, Santa Clara, CA (US); Qiwei Liang, Santa Clara, CA (US); Jang-Gyoo Yang, Santa Clara, CA (US)

(73) Assignee: Applied Materials, Inc., Santa Clara, CA (US)

(21) Appl. No.: 13/669,164

(22) Filed: Nov. 5, 2012

Related U.S. Application Data
(60) Provisional application No. 61/557,271, filed on Nov. 8, 2011.

(51) Int. Cl. B05B 1/18

(52) U.S. Cl. CPC B05B 1/185
USPC 239/418

(57) ABSTRACT

Showerheads are described including a first plurality of apertures configured to receive a first fluid that may be distributed to a processing region of a semiconductor substrate processing chamber. The first plurality of apertures may include a first set of apertures and a second set of apertures, and the first set of apertures may have an aperture diameter that is greater than the aperture diameter of the second set of apertures. The showerheads may also have a second plurality of apertures configured to receive a second fluid to be distributed to the processing region of the substrate processing chamber. The showerhead may be configured to maintain the first and second fluids fluidly isolated prior to their distribution to the processing region.

### CROSS-REFERENCES TO RELATED APPLICATIONS

This application claims the benefit of U.S. Provisional Application No. 61/557,271, filed Nov. 8, 2011, entitled “Precursor Distribution Features for Improved Deposition Uniformity,” the entire disclosure of which is hereby incorporated by reference for all purposes.

### FIELD OF THE TECHNOLOGY

The present technology is related to semiconductor manufacturing processes and equipment. More specifically, the present technology is related to semiconductor processing equipment to improve deposition uniformity.

### BACKGROUND

Semiconductor device geometries have dramatically decreased in size since their introduction decades ago. Modern semiconductor fabrication equipment routinely produces devices with 45 nm, 32 nm, and 28 nm feature sizes, and new equipment is being developed and implemented to make devices with even smaller geometries. As feature dimensions continue to decrease across the surface of a substrate wafer, issues may arise relating to layer uniformity across the surface of the substrate.

For example, if the flow of material to the substrate is not uniform, the thickness of the deposited material may be dissimilar across the surface of the substrate, with areas having too much deposited material, and/or areas having too little deposited material. If areas receive too little material, gaps in coverage may be produced, which may eventually cause short circuiting within the devices.

Thus, there is a need for new fabrication processes and equipment that may improve the uniformity of deposited material across the surface of a substrate. These and other benefits are provided by the disclosed technology.

### BRIEF SUMMARY

Showerheads are described including a first plurality of apertures configured to receive a first fluid that may be distributed to a processing region of a semiconductor substrate processing chamber. The first plurality of apertures may include a first set of apertures and a second set of apertures, and the first set of apertures may have an aperture diameter that is greater than the aperture diameter of the second set of apertures. The showerheads may also have a second plurality of apertures configured to receive a second fluid to be distributed to the processing region of the substrate processing chamber. The showerhead may be configured to maintain the first and second fluids fluidly isolated prior to their distribution to the processing region.

The first plurality of apertures may be distributed in the showerhead in concentric rings, and the rings may comprise a geometric pattern. Each outwardly located concentric ring may comprise an increasing number of apertures to maintain a similar geometric pattern at an increased diameter. At least one of the concentric rings of apertures may comprise apertures from the second set of apertures. In disclosed embodiments at least one of the concentric rings of apertures may include no aperture in at least one of the locations that would otherwise contain an aperture to maintain the geometric pattern from an inwardly located one of the concentric rings

The showerhead may include at least six concentric rings of apertures, where at least one of the rings of apertures between the innermost and outermost rings of apertures consists of apertures from the second set of apertures. Disclosed showerheads may include at least five concentric rings of apertures where the first two innermost rings and the last two outermost rings may be radially offset from the adjacent ring by a first length. At least two of the rings may be offset by at least twice the first length without a ring of apertures disposed between the two rings radially.

Disclosed showerheads may include at least nine concentric rings of apertures, where at least one ring of apertures of rings three through six of outwardly numbered rings includes apertures from the second set of apertures. At least two rings of apertures of rings three through six of outwardly numbered rings may also include apertures from the second set of apertures. In disclosed showerheads the first plurality of apertures may be defined in a first plate, and the second plurality of apertures may be defined in a second plate. The first and second plates may be coupled with one another such that a volume is defined between the first and second plates. The showerhead may be configured to receive the second fluid into the volume defined between the first and second plates, and may be configured to prevent access by the second fluid through the first plate.

The disclosed technology also includes gas distribution assemblies that include an annular body having an inner annular wall located at an inner diameter, an outer annular wall located at an outer diameter, an upper surface, and a bottom surface. An upper recess may be formed in the upper surface, a lip may be formed radially outward of the inner wall and located toward the bottom surface, and a seat may be formed in the inner annular wall and located toward the bottom surface. The assembly may include an upper plate coupled with the upper recess of the annular body, the upper plate defining a plurality of first apertures. The assembly may also include a bottom plate coupled with the seat formed in the inner annular wall of the annular body. The bottom plate may include a plurality of second apertures formed in the plate, where the second apertures align with the first apertures. The bottom plate may also include a plurality of third apertures formed in the plate that are located in the plate between the second apertures. The first and second apertures may be aligned and form a pattern of concentric geometric shapes of first and second apertures on the upper and lower plates, and a first subset of the first and second apertures may comprise an aperture diameter that is less than the aperture diameter of a second subset of the first and second apertures. The third apertures may have an hourglass shape.

The gas distribution assemblies may have the bottom plate sealingly coupled with the upper plate such that the aligned first and second apertures are fluidly isolated from the third apertures. The concentric geometric shapes of apertures on the bottom plate may include at least two rings of apertures, and the rings may have an increasing diameter from one another radially outward. The apertures forming each ring may be of the same aperture diameter as the other apertures contained in that ring, and at least one of the rings of first and second apertures may have aperture diameters that are different than the aperture diameters of the first and second apertures located in a second ring.

The gas distribution assemblies may have the upper plate and bottom plate joined together forming a seal around each pair of aligned first and second apertures, wherein the upper plate is welded to the annular body creating a seal between an outer edge of the upper plate and an inner edge of the upper recess. The bottom plate may be welded to the annular body such that a seal is created between an outer edge of the bottom plate and the inner annular wall. The annular body may further include a first sealing channel formed on the upper surface of the annular body radially outward of the upper recess, and a second sealing channel formed on the bottom surface of the annular body radially outward of the upper recess.

The annular body may further include fluid delivery channels formed into the upper recess radially inward of the first fluid channel. Fluid passages may be formed into the upper recess radially inward of the fluid delivery channels that are coupled with the fluid delivery channels. A conduit may be formed through the outer annular wall of the annular body and fluidly coupled with the fluid delivery channels to form a flow path from an inlet of the conduit to an outlet of the plurality of third apertures. The annular body may also include a heater recess formed in the bottom surface of the annular body radially outward of the second cooling channel.

Methods are also described for flowing precursor gases through a showerhead such as those described throughout the disclosure. A first precursor may be flowed through a first plurality of apertures in the showerhead and may be delivered into a processing region of a semiconductor processing chamber. The first plurality of apertures may include a first set of apertures and a second set of apertures where the first set of apertures have an aperture diameter that may be greater than the aperture diameter of the second set of apertures. The first precursor may be delivered through the first plurality of apertures such that a substantially equivalent amount of the first precursor is delivered through each of the plurality of first apertures.

Additional embodiments and features are set forth in part in the description that follows, and in part will become apparent to those skilled in the art upon examination of the specification or may be learned by the practice of the technology. The features and advantages of the technology may be realized and attained by means of the instrumentalities, combinations, and methods described in the specification.

### BRIEF DESCRIPTION OF THE DRAWINGS

A further understanding of the nature and advantages of the disclosed embodiments may be realized by reference to the remaining portions of the specification and the drawings.

FIG. 1 is a top plan view of one embodiment of a processing tool;

FIGS. 2A-2C are schematic cross-sectional views of one embodiment of a processing chamber;

FIGS. 3A-3M are schematic views of one embodiment of a showerhead as described herein;

FIGS. 4A-4I are schematic views of one embodiment of a gas distribution assembly as described herein;

FIG. 5 shows a cross-sectional view of a showerhead during operation and the associated processing fluid flow.

FIG. 6 is a graph showing deposition characteristics across the surface of a substrate for two showerhead designs.

In the appended figures, similar components and/or features may have the same numerical reference label. Further, various components of the same type may be distinguished by following the reference label by a letter that distinguishes among the similar components and/or features. If only the first numerical reference label is used in the specification, the description is applicable to any one of the similar components and/or features having the same first numerical reference label irrespective of the letter suffix.

### DETAILED DESCRIPTION

The present technology includes improved showerhead designs for distributing processing gases in an improved flow pattern for forming deposition layers on a semiconductor substrate of a more uniform height. While conventional showerhead designs may simply provide pass-through distribution systems for processing and precursor gases, the presently described technology allows for improved control of the flow characteristics of gases as they are delivered to a substrate processing chamber. In so doing, deposition operations may produce films of a substantially equivalent height across an entire substrate.

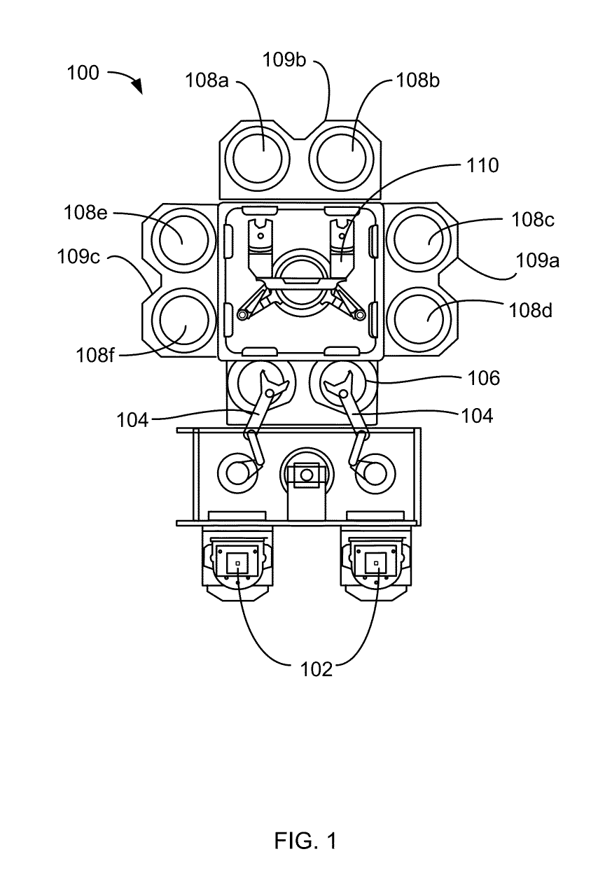

FIG. 1 is a top plan view of one embodiment of a processing tool 100 of deposition, baking, and curing chambers according to disclosed embodiments. In the figure, a pair of FOUPs (front opening unified pods) 102 supply substrates (e.g., 300 mm diameter semiconductor wafers) that may be received by robotic arms 104 and placed into a low pressure holding area 106 before being placed into one of the substrate processing sections 108a-f of the tandem process chambers 109a-c. A second robotic arm 110 may be used to transport the substrates from the holding area 106 to the processing chambers 108a-f and back.

The substrate processing sections 108a-f of the tandem process chambers 109a-c may include one or more system components for depositing, annealing, curing and/or etching a flowable dielectric film on the substrate. In one configuration, two pairs of the tandem processing sections of the processing chamber (e.g., 108c-d and 108e-f) may be used to deposit the flowable dielectric material on the substrate, and the third pair of tandem processing sections (e.g., 108a-b) may be used to anneal the deposited dielectric. In another configuration, the two pairs of the tandem processing sections of processing chambers (e.g., 108c-d and 108e-f) may be configured to both deposit and anneal a flowable dielectric film on the substrate, while the third pair of tandem processing sections (e.g., 108a-b) may be used for UV or E-beam curing of the deposited film. In still another configuration, all three pairs of tandem processing sections (e.g., 108a-f) may be configured to deposit and cure a flowable dielectric film on the substrate.

In yet another configuration, two pairs of tandem processing sections (e.g., 108c-d and 108e-f) may be used for both deposition and UV or E-beam curing of the flowable dielectric, while a third pair of tandem processing sections (e.g. 108a-b) may be used for annealing the dielectric film. It will be appreciated that additional configurations of deposition, annealing, and curing chambers for flowable dielectric films are contemplated by system 100.

In addition, one or more of the tandem processing sections 108a-f may be configured as a wet treatment chamber. These process chambers may include heating the flowable dielectric film in an atmosphere that includes moisture. Thus, embodiments of system 100 may include wet treatment tandem processing sections 108a-b and anneal tandem processing sections 108c-d to perform both wet and dry anneals on the deposited dielectric film.

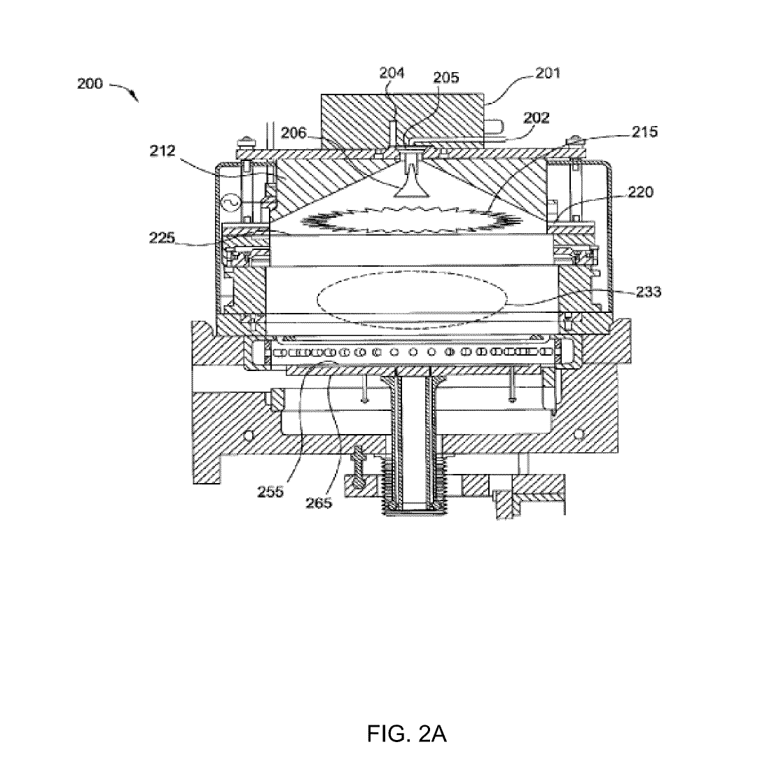

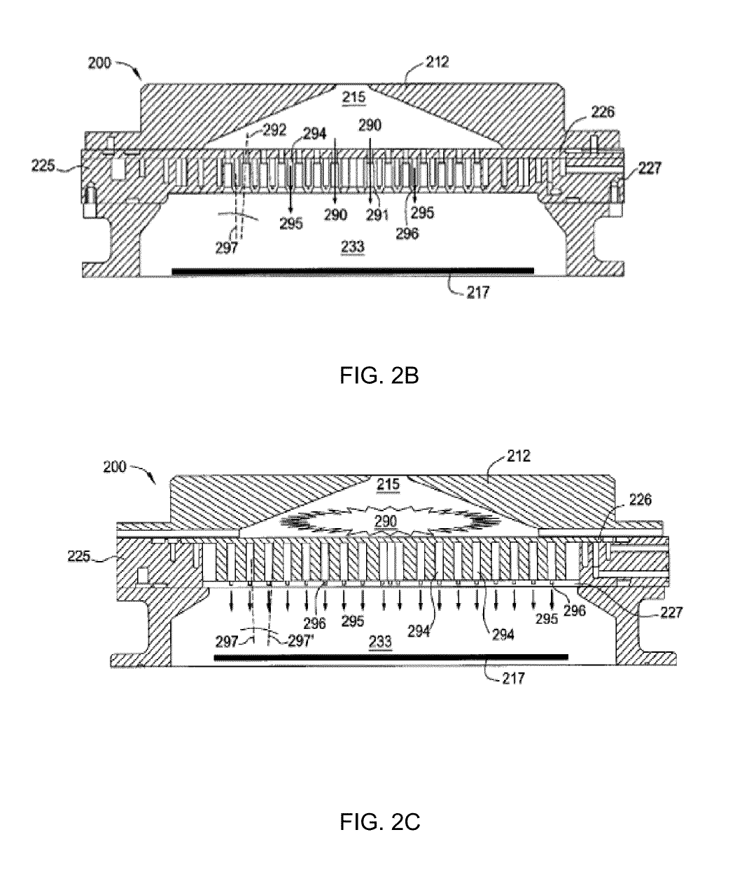

FIG. 2A is a cross-sectional view of one embodiment of a process chamber section 200 with partitioned plasma generation regions within the tandem processing chambers. During film deposition (silicon oxide, silicon nitride, silicon oxynitride, or silicon oxycarbide), a process gas may be flowed into the first plasma region 215 through a gas inlet assembly 205. The process gas may be excited prior to entering the first plasma region 215 within a remote plasma system (RPS) 201. A lid 212, a showerhead 225, and a substrate support 265, having a substrate 255 disposed thereon, are shown according to disclosed embodiments. The lid 212 may be pyramidal, conical, or of another similar structure with a narrow top portion expanding to a wide bottom portion. The lid 212 is depicted with an applied AC voltage source and the showerhead 225 is grounded, consistent with plasma generation in the first plasma region 215. An insulating ring 220 may be positioned between the lid 212 and the showerhead 225 enabling a capacitively coupled plasma (CCP) to be formed in the first plasma region.

The lid 212 may be a dual-source lid for use with a processing chamber according to disclosed embodiments. A fluid inlet assembly 205 may introduce a fluid, such as a gas, into the first plasma region 215. Two distinct fluid supply channels are visible within the fluid inlet assembly 205. A first channel 202 may carry a fluid, such as a gas, that passes through the remote plasma system (“RPS”) 201, while a second channel 204 may carry a fluid, such as a gas, that bypasses the RPS 201. The first channel 202 may be used for the process gas and the second channel 204 may be used for a treatment gas in disclosed embodiments. The gases may flow into the plasma region 215 and be dispersed by a baffle 206. The lid 205 and showerhead 225 are shown with an insulating ring 220 in between, which allows an AC potential to be applied to the lid 212 relative to the showerhead 225.

A fluid, such as a precursor, for example a silicon-containing precursor, may be flowed into the second plasma region by embodiments of the showerhead described herein. Excited species derived from the process gas in the plasma region 215 may travel through apertures in the showerhead 225 and react with the precursor flowing into the second plasma region 233 from the showerhead. Little or no plasma may be present in the second plasma region 233. Excited derivatives of the process gas and the precursor may combine in the region above the substrate and, on occasion, on the substrate to form a flowable film on the substrate. As the film grows, more recently added material possesses a higher mobility than underlying material. Mobility may decrease as organic content is reduced by evaporation. Gaps may be filled by the flowable film using this technique without leaving traditional densities of organic content within the film after deposition is completed. A curing step may still be used to further reduce or remove the organic content from a deposited film.

Exciting the process gas in the first plasma region 215 directly, exciting the process gas in the RPS, or both, may provide several benefits. The concentration of the excited species derived from the process gas may be increased within the second plasma region 233 due to the plasma in the first plasma region 215. This increase may result from the location of the plasma in the first plasma region 215. The second plasma region 233 may be located closer to the first plasma region 215 than the remote plasma system (RPS) 201, leaving less time for the excited species to leave excited states through collisions with other gas molecules, walls of the chamber, and surfaces of the showerhead.

The uniformity of the concentration of the excited species derived from the process gas may also be increased within the second plasma region 233. This may result from the shape of the first plasma region 215, which may be more similar to the shape of the second plasma region 233. Excited species created in the remote plasma system (RPS) 201 may travel greater distances in order to pass through apertures near the edges of the showerhead 225 relative to species that pass through apertures near the center of the showerhead 225. The greater distance may result in a reduced excitation of the excited species and, for example, may result in a slower growth rate near the edge of a substrate. Exciting the process gas in the first plasma region 215 may mitigate this variation.

The processing gas may be excited in the RPS 201 and may be passed through the showerhead 225 to the second plasma region 233 in the excited state. Alternatively, power may be applied to the first processing region to either excite a plasma gas or enhance an already exited process gas from the RPS. While a plasma may be generated in the second plasma region 233, a plasma may alternatively not be generated in the second plasma region. In one example, the only excitation of the processing gas or precursors may be from exciting the processing gas in the RPS 201 to reaction with the precursors in the second plasma region 233.

The processing chamber and tool are more fully described in patent application Ser. No. 12/210,940 filed on Sep. 15, 2008, and patent application Ser. No. 12/210,982 filed on Sep. 15, 2008, which are incorporated herein by reference to the extent not inconsistent with the claimed aspects and description herein.

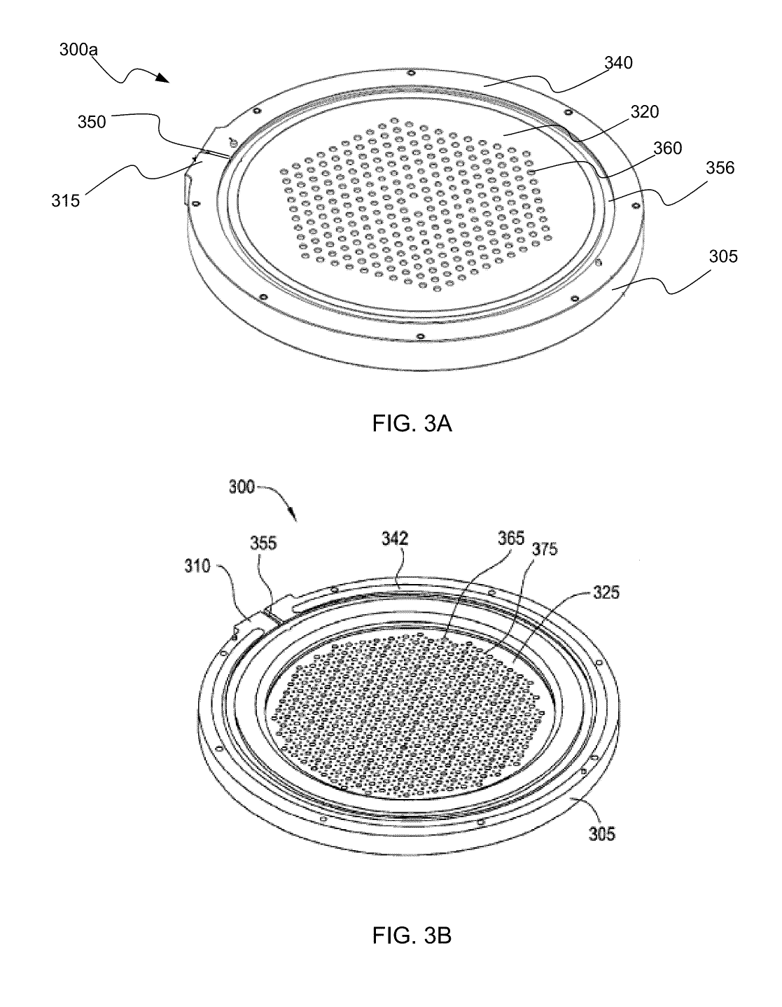

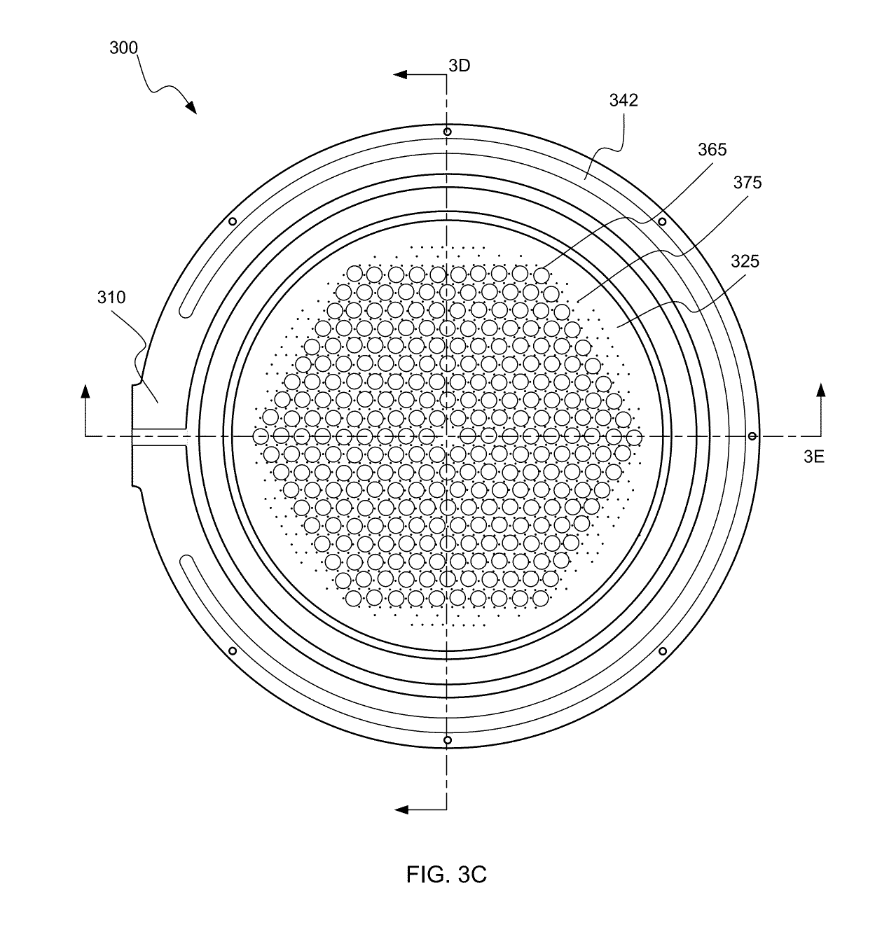

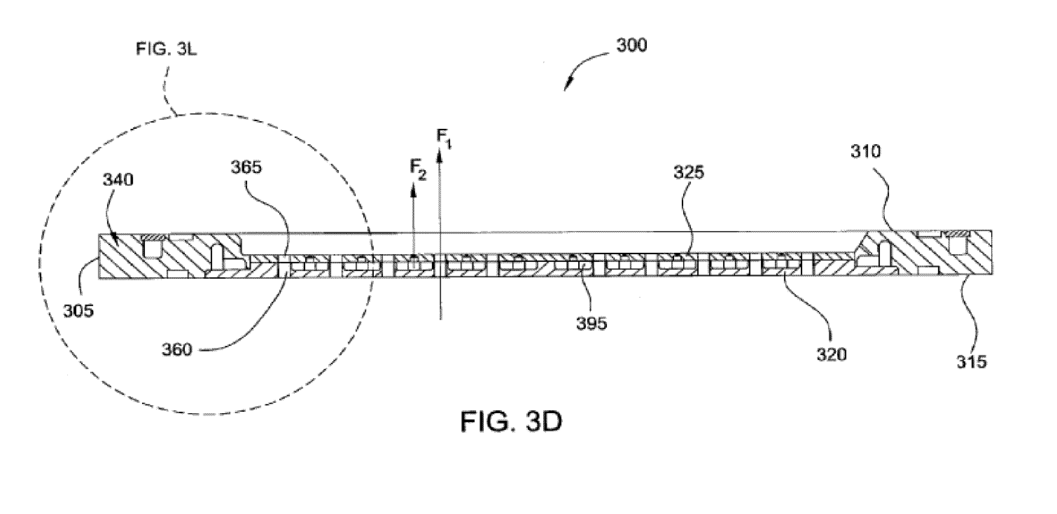

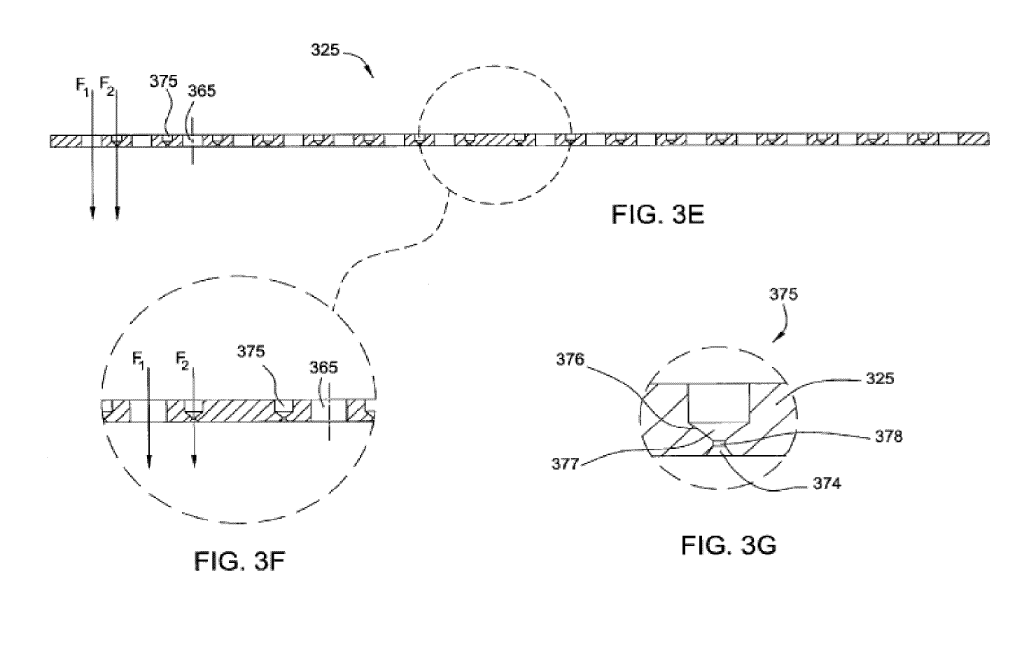

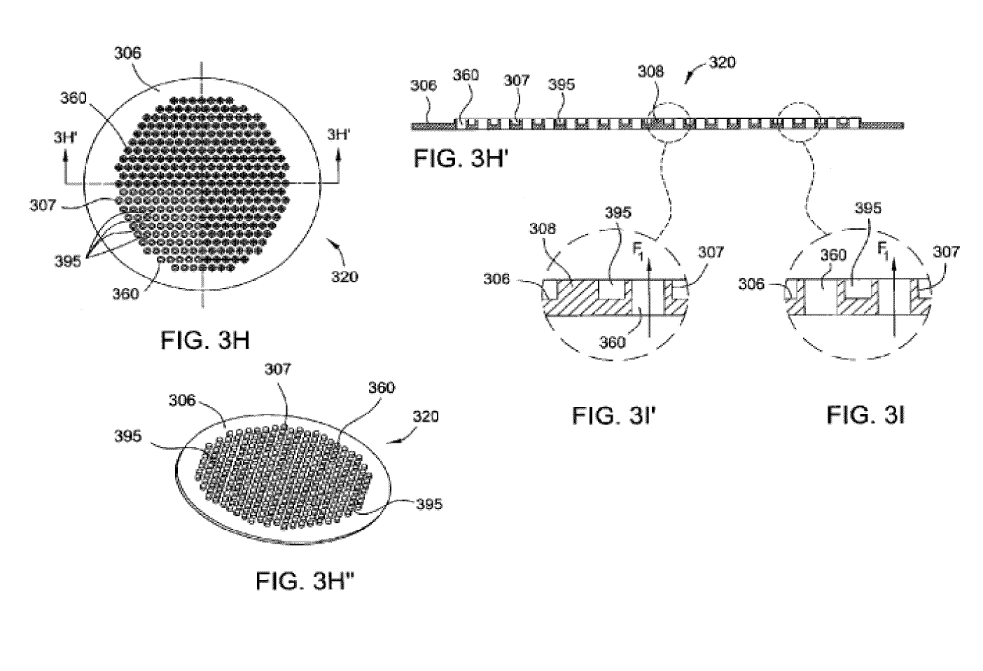

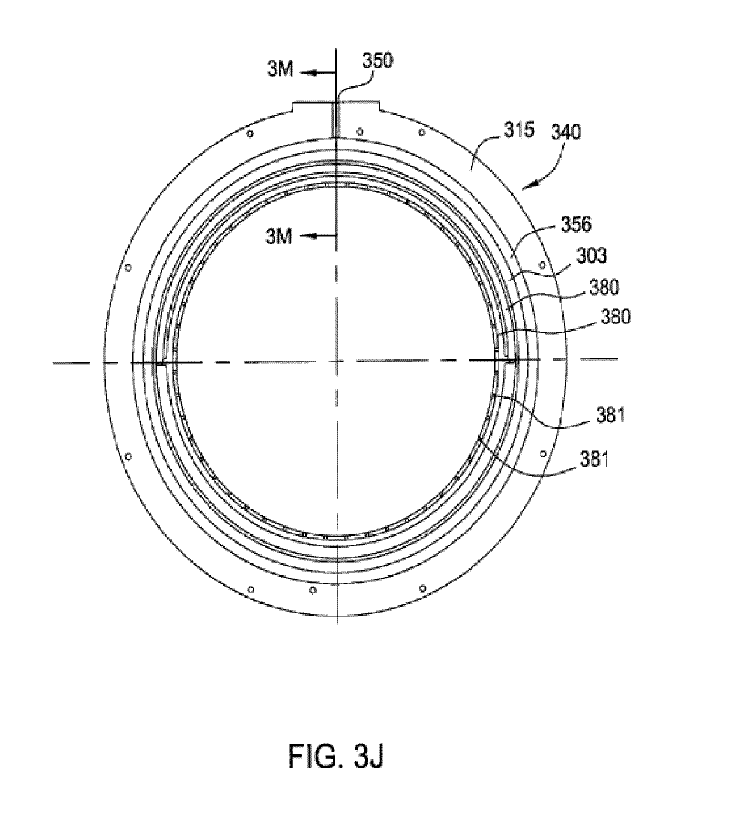

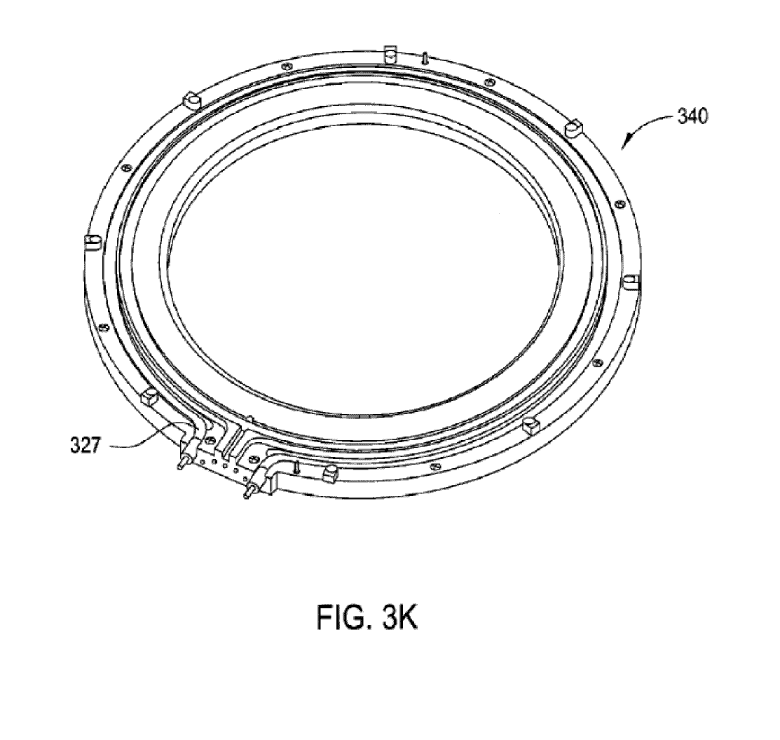

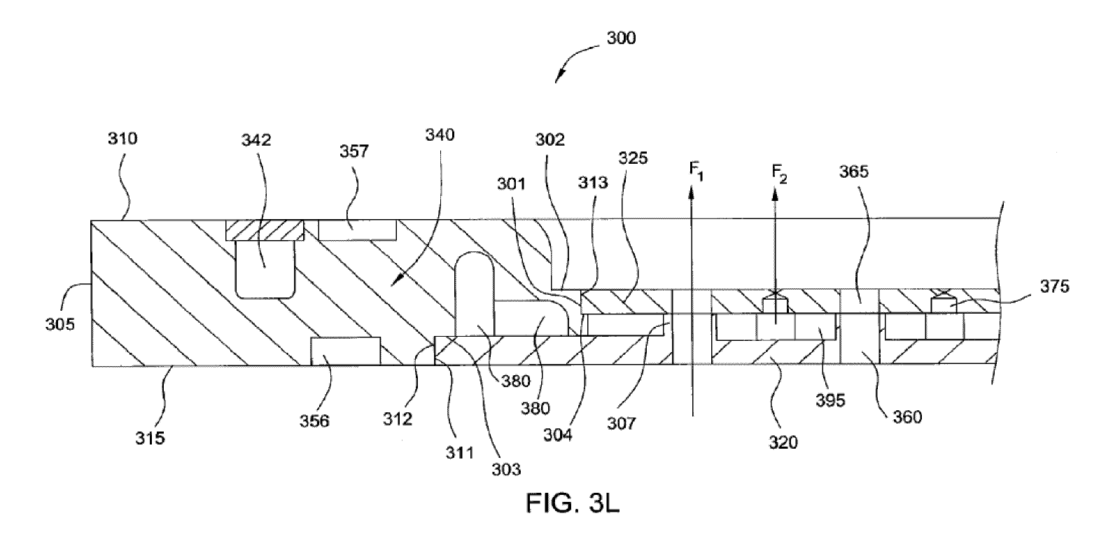

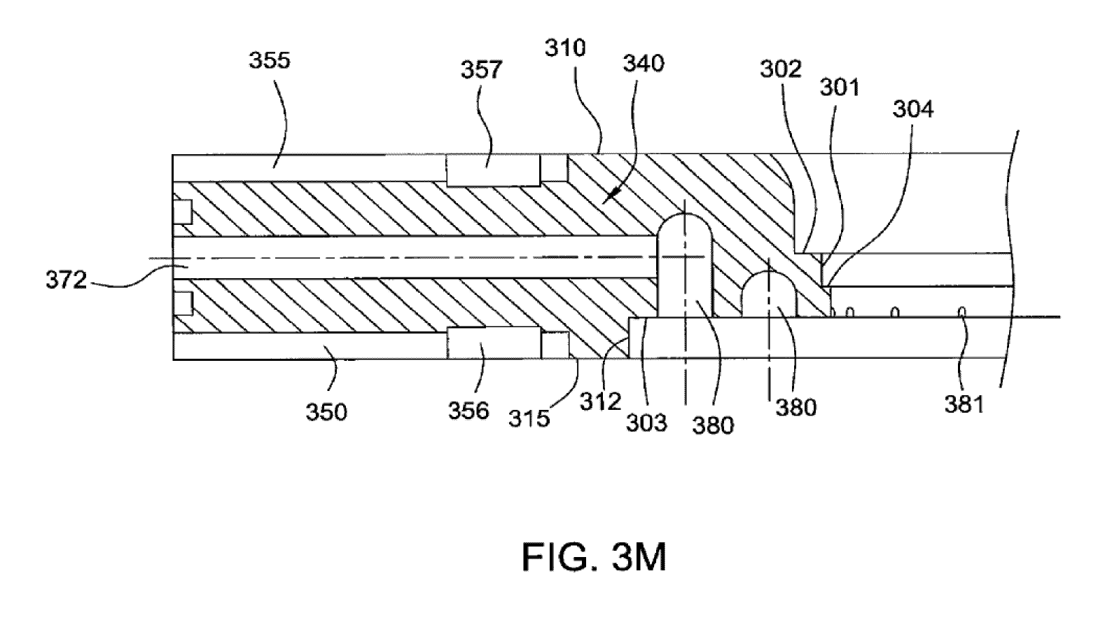

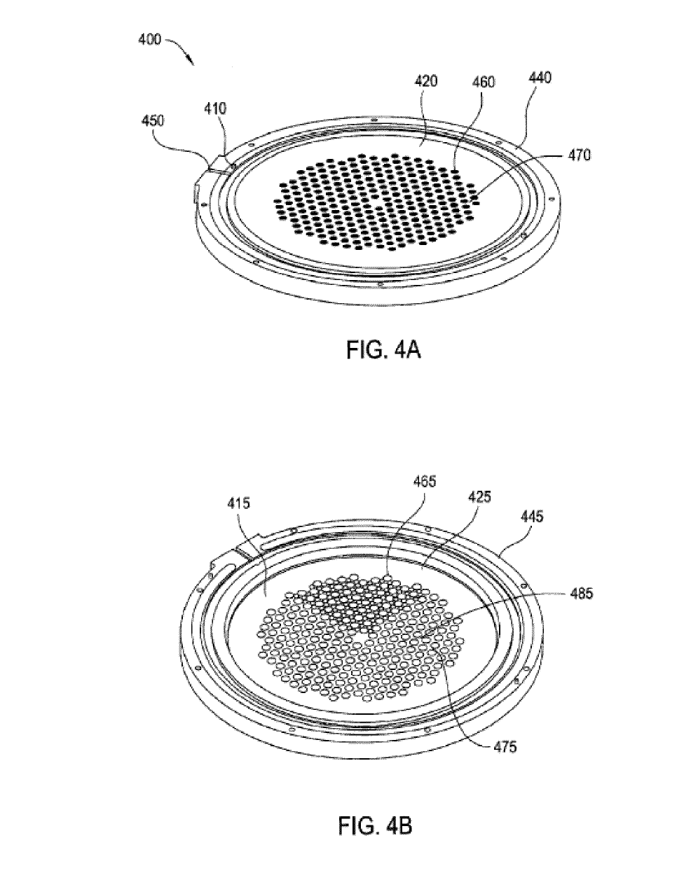

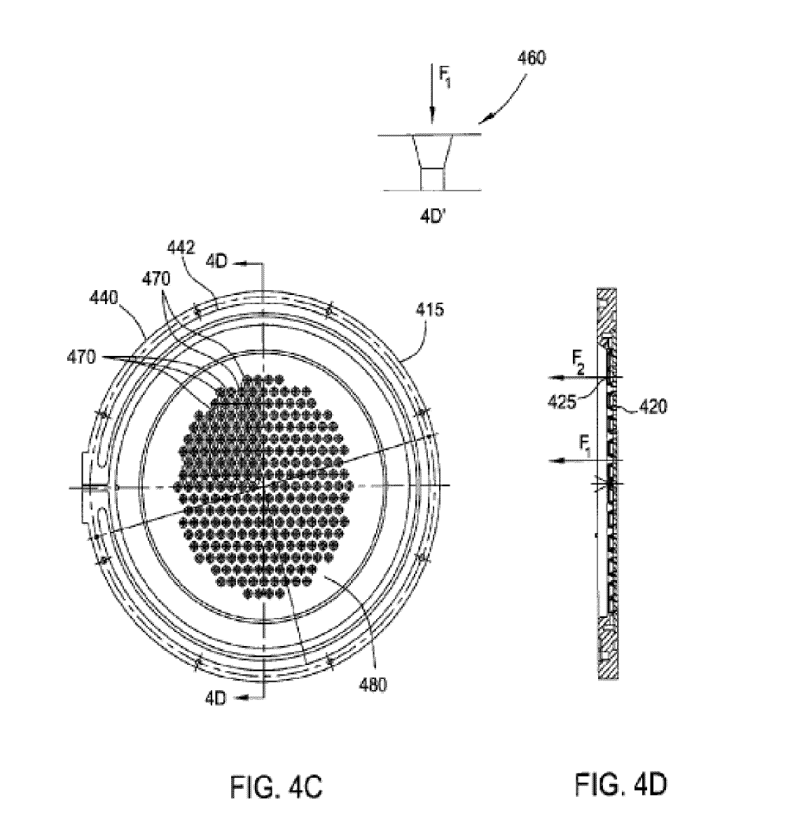

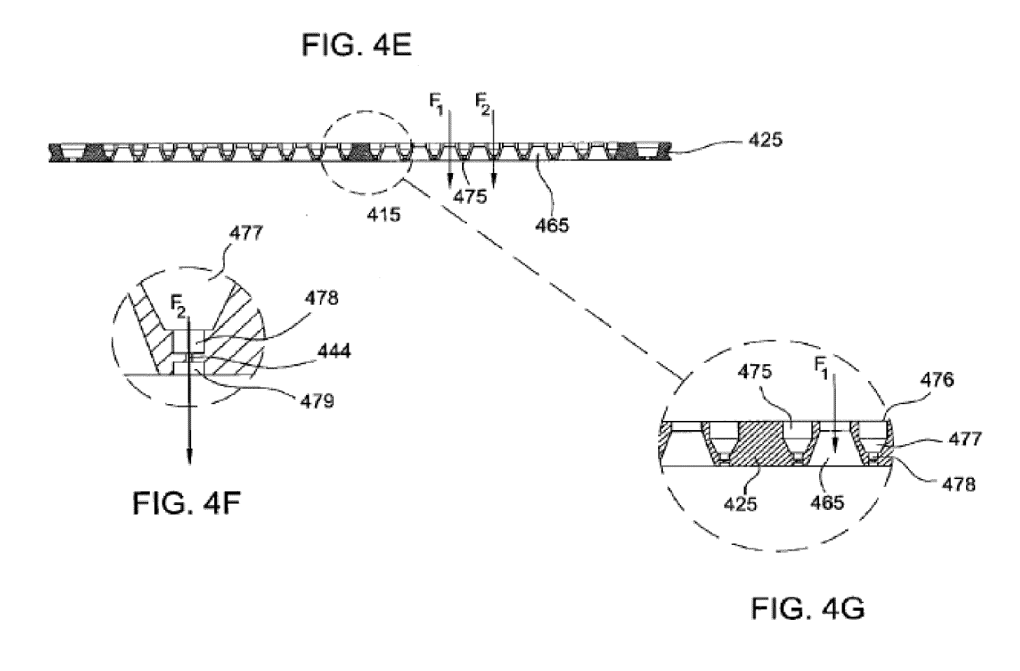

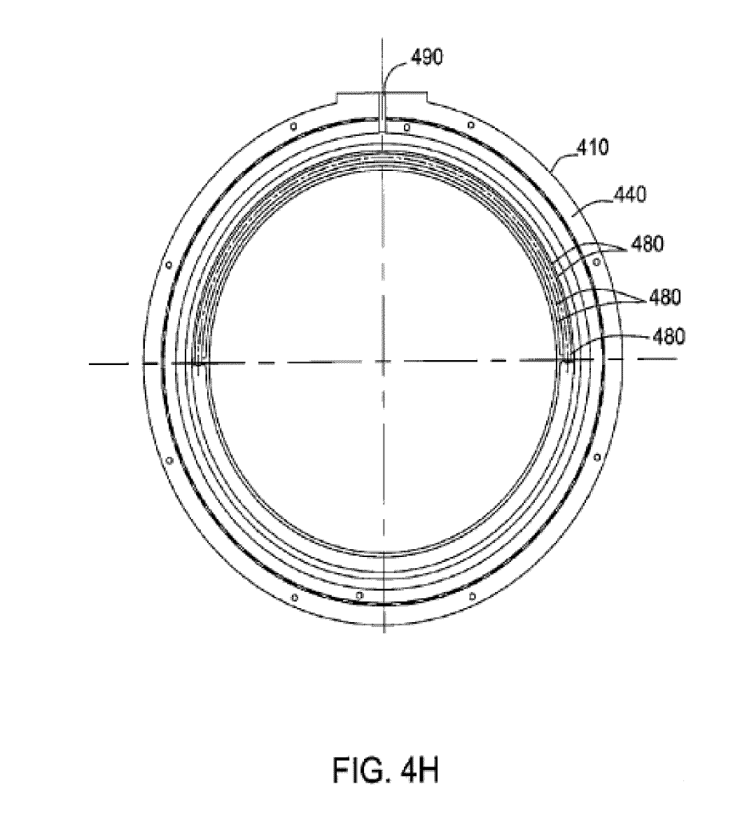

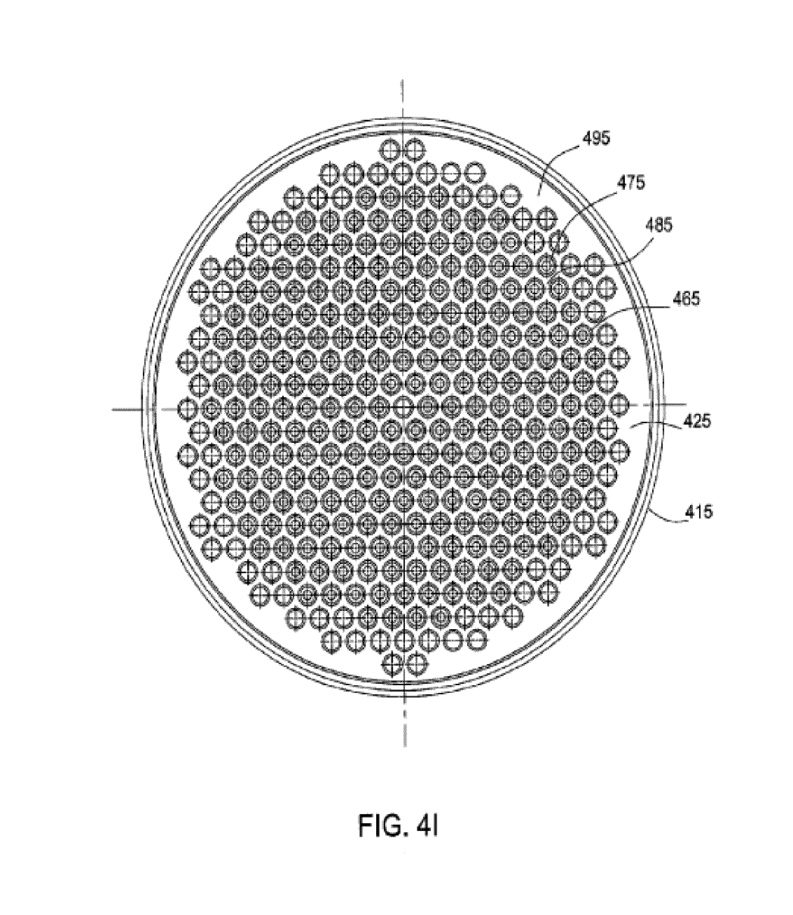

FIGS. 2B-2C are side schematic views of one embodiment of the precursor flow processes in the processing chambers and the gas distribution assemblies described herein. The gas distribution assemblies for use in the processing chamber section 200 are referred to as dual zone showerheads (DZSH) and are detailed in the embodiments described in FIGS. 3A-3K, 4A-4I herein. The following gas flow description is directed towards a broad dual zone showerhead description and should not be interpreted or construed as limiting the showerhead aspects described herein. While the following description is described with the deposition of dielectric materials, the inventors contemplate that this apparatus and associated methods may be used to deposit other materials.

The dual zone showerhead may allow for flowable deposition of a dielectric material. Examples of dielectric materials that may be deposited in the processing chamber include silicon oxide, silicon nitride, silicon oxycarbide, or silicon oxynitride. Silicon nitride materials include silicon nitride, SiₓN_{y}, hydrogen-containing silicon nitrides, SiₓN_{y}H_{z}, silicon oxynitrides including hydrogen-containing silicon oxynitrides, SiₓN_{y}H_{z}O_{zz}, and halogen-containing silicon nitrides including chlorinated silicon nitrides, SiₓN_{y}H_{z}Cl_{zz}. The deposited dielectric material may then be converted to a silicon oxide like material.

The dielectric layer may be deposited by introducing dielectric material precursors and reacting the precursors with a processing gas in the second plasma region 233, or reaction volume. Examples of precursors are silicon-containing precursors including silane, disilane, methylsilane, dimethylsilane, trimethylsilane, tetramethylsilane, tetraethoxysilane (TEOS), triethoxysilane (TES), octamethylcyclotetrasiloxane (OMCTS), tetramethyl-disiloxane (TMDSO), tetramethylcyclotetrasiloxane (TMCTS), tetramethyl-diethoxyl-disiloxane (TMDDSO), dimethyl-dimethoxyl-silane (DMDMS) or combinations thereof. Additional precursors for the deposition of silicon nitride include SiₓN_{y}H_{z}-containing precursors, such as silyl-amine and its derivatives including trisilylamine (TSA) and disilylamine (DSA), SiₓN_{y}H_{z}O_{zz}-containing precursors, SiₓN_{y}H_{z}Cl_{zz}-containing precursors, or combinations thereof.

Processing gases include hydrogen-containing compounds, oxygen-containing compounds, nitrogen-containing compounds, or combinations thereof. Examples of suitable processing gases include one or more of compounds selected from the group comprising H₂, an H₂/N₂ mixture, NH₃, NH₄OH, O₃, O₂, H₂O₂, N₂, NₓH_{y} compounds including N₂H₄ vapor, NO, N₂O, NO₂, water vapor, or combinations thereof. The processing gas may be plasma exited, such as in the RPS unit, to include N* and/or H* and/or O*-containing radicals or plasma, for example, NH₃, NH₂*, NH*, N*, H*, O*, N*O*, or combinations thereof. The process gas may alternatively include one or more of the precursors described herein. Additional gases such as carrier gases may be included as well, and may include H₂, N₂, He, Ar, etc., and combinations thereof.

The precursors may be introduced into the reaction zone by first being introduced into an internal showerhead volume 294 defined in the showerhead 225 by a first manifold 226, or upper plate, and second manifold 227, or bottom plate. The precursors in the internal showerhead volume 294 may flow 295 into the processing region 233 via apertures 296 (openings) formed in the second manifold. This flow path may be isolated from the rest of the process gases in the chamber, and may provide for the precursors to be in an unreacted or substantially unreacted state until entry into the processing region 233 defined between the substrate 217 and a bottom of the second manifold 227. Once in the processing region 233, the precursor may react with a processing gas. The precursor may be introduced into the internal showerhead volume 294 defined in the showerhead 225 through a side channel formed in the showerhead, such as channels 490, 518, and/or 539 as shown in the showerhead embodiments herein. The process gas may be in a plasma state including radicals from the RPS unit or from a plasma generated in the first plasma region. Additionally, a plasma may be generated in the second plasma region.

Processing gases may be provided into the first plasma region 215, or upper volume, defined by the lid 212 and the top of the showerhead 225. Distribution of the processing gas may be achieved by use of a baffle 206 as shown in FIG. 2A. The processing gas may be plasma excited in the first plasma region 215 to produce process gas plasma and radicals including N* and/or H* and/or O* containing radicals or plasma, for example, NH₃, NH₂*, NH*, N*, H*, O*, N*O*, or combinations thereof. Alternatively, the processing gas may already be in a plasma state after passing through a remote plasma system prior to introduction to the first plasma processing region 215.

The processing gas 290 including plasma and radicals may then be delivered to the processing region 233 for reaction with the precursors though apertures, such as channels 290. The processing gasses passing though the channels may be physically isolated from the internal showerhead volume 294 and may not react with the precursors passing through the internal showerhead volume 294 as both the processing gas and the precursors pass through the showerhead 225. Once in the processing volume, the processing gas and precursors may mix and react to deposit dielectric materials.

In addition to the process gas and a dielectric material precursor, there may be other gases introduced at varied times for varied purposes. A treatment gas may be introduced to remove unwanted species from the chamber walls, the substrate, the deposited film and/or the film during deposition, the treatment gas containing compounds including hydrogen, carbon, or fluorine—such as NF₃, for example. A process gas and/or treatment gas may comprise at least one of the gases from the group: H₂, an H₂/N₂ mixture, NH₃, NH₄OH, O₃, O₂, H₂O₂, N₂, N₂H₄ vapor, NO, N₂O, NO₂, water vapor, or combinations thereof. A treatment gas may be excited in a plasma and then used to reduce or remove a residual organic content from the deposited film. In other disclosed embodiments the treatment gas may be used without a plasma. When the treatment gas includes water vapor, the delivery may be achieved using a mass flow meter (MFM), an injection valve, or by commercially available water vapor generators. The treatment gas may be introduced from into the first processing region, either through the RPS unit or bypassing the RPS unit, and may further be excited in the first plasma region.

The axis 292 of the opening of apertures 291 and the axis 297 of the opening of apertures 296 may be parallel or substantially parallel to one another. Alternatively, the axis 292 and axis 297 may be angled from each other, such as from about 1° to about 80°, for example, from about 1° to about 30°. Alternatively, each of the respective axis 292 may be angled from each other, such as from about 1° to about 80°, for example, from about 1° to about 30°, and each of the respective axis 297 may be angled from each other, such as from about 1° to about 80°, for example, from about 1° to about 30°.

The respective openings may be angled, such as shown for aperture 291 in FIG. 2B, with the opening having an angle from about 1° to about 80°, such as from about 1° to about 30°. The axis 292 of the opening of apertures 291 and the axis 297 of the opening of apertures 296 may be perpendicular or substantially perpendicular to the surface of the substrate 217. Alternatively, the axis 292 and axis 297 may be angled from the substrate surface, such as less than about 5°.

FIG. 2C illustrates a partial schematic view of the processing chamber 200 and showerhead 225 illustrating the precursor flow 295 from the internal volume 294 through apertures 296 into the processing region 233. The figure also illustrates an alternative embodiment showing axis 297 and 297′ of two apertures 296 being angled from one another.

FIG. 3A illustrates an upper perspective view of a gas distribution assembly 300a. In usage, the gas distribution system 300 may have a substantially horizontal orientation such that an axis of the gas apertures formed therethrough may be perpendicular or substantially perpendicular to the plane of the substrate support (see substrate support 265 in FIG. 2A). FIG. 3B illustrates a bottom perspective view of a gas distribution assembly 300. FIG. 3C is a bottom plan view of the gas distribution assembly 300. FIG. 3D is a cross sectional view of the gas distribution assembly 300 taken along line 3D-3D of FIG. 3C. FIG. 3E is a cross sectional view of a bottom plate 325 of the gas distribution assembly 300 taken along line 3E-3E of FIG. 3C. FIGS. 3F and 3G are magnified views of features of the bottom plate 325. FIG. 3H is a bottom plan view of an upper plate 320 of the gas distribution assembly 300. FIG. 3H′ is a cross sectional view of the upper plate 320 taken along line 3H′-3H′ of FIG. 3H. FIG. 3H″ is a bottom perspective view of the upper plate 320. FIGS. 3I and 3I′ are magnified views of features of the upper plate 320. FIG. 3J is a top view of an annular body 340 of the gas distribution assembly 300. FIG. 3K illustrates a perspective view of the bottom of the annular body 340 having a heating element 327 disposed therein. FIG. 3L is a magnified view of a portion of the gas distribution assembly 300 shown in FIG. 3D. FIG. 3M is a cross sectional view of the annular body 340 taken across line 3M-3M of FIG. 3J.

Referring to FIGS. 3A-M, the gas distribution assembly 300 generally includes the annular body 340, the upper plate 320, and the bottom plate 325. The annular body 340 may be a ring which has an inner annular wall 301, an inner lip 302, which extends radially outward from the inner annular wall 301, an upper recess 303, a seat 304, and an outer wall 305, as seen especially in FIG. 3L. The annular body 340 has a top surface 315 and a bottom surface 310 which define the thickness of the annular body 340. A channel 356 may be located in the top and bottom surface in which a sealing member, such as an o-ring, may be disposed to sealingly couple the assembly 300 in the processing chamber. Conduits 350, 355 may be formed in the top and bottom surface and fluidly coupled the channels 356 for purging air to ensure a fitted seal. A heater recess 342 may be formed in the bottom surface 310 and be adapted to hold a heating element 327, as shown in FIG. 3K. Additionally, a cooling channel (not shown) may be disposed within the annular body through which a fluid may be run to cool the assembly during operation.

The upper plate 320 may be a disk-shaped body, having a diameter selected to mate with the diameter of the upper recess 303, with a number of first apertures 360 formed therethrough, as especially seen in FIGS. 3D and 3H-I′. The first apertures 360 may extend beyond a bottom surface 306 of the upper plate 320 thereby forming a number of raised cylindrical bodies 307. In between each raised cylindrical body 307 may be a gap 395. As seen in FIGS. 3H and 3H″, the first apertures 360 may be arranged in a polygonal pattern on the upper plate 320, such that an imaginary line drawn through the centers of the outermost first apertures 360 define a polygonal figure, which may be for example, a six-sided polygon.

The pattern may also feature an array of staggered rows from about 5 to about 60 rows, such as from about 15 to about 25 rows, such as for example, about 21 rows, of first apertures 360. Each row may have, along the y-axis, from about 5 to about 20 first apertures 360, such as from about 6 to about 18 apertures, with each row being spaced between about 0.4 and about 0.7 inches apart, for example, about 0.54 inches apart. Each first aperture 360 in a row may be displaced along the x-axis from a prior aperture between about 0.4 and about 0.8 inches, such as about 0.63 inches, from each respective diameter. The first apertures 360 may be staggered along the x-axis from an aperture in another row by between about 0.2 and about 0.4 inches, such as about 0.32 inches, from each respective diameter. The first apertures 360 may be equally spaced from one another in each row.

At the center of the upper plate 360 there may be a protrusion 308 instead of a first aperture 360, as shown in FIG. 3I′. The protrusion 308 may extend to the same height as the raised cylindrical bodies 307. Alternatively, the center of the upper plate may have no aperture or protrusion.

The bottom plate 325 may have a disk-shaped body having a number of second apertures 365 and third apertures 375 formed therethrough, as especially seen in FIGS. 3C and 3E-G. The bottom plate 325 may have a uniform thickness, from about 0.1 to about 0.2 inches, such as about 0.15 inches, and a diameter that mates with the diameter of the inner annular wall 301 of the annular body 340. The second apertures 365 may be arranged in a pattern that aligns with the pattern of the first apertures 360 as described above. In one embodiment, when the upper plate 320 and bottom plate 325 are positioned one on top of the other, the axes of the first apertures 360 and second apertures 365 align. The plurality of first apertures 360 and the plurality of second apertures 365 may have their respective axes parallel or substantially parallel to each other, for example, the apertures 360, 365 may be concentric. Alternatively, the plurality of first apertures 360 and the plurality of second apertures 365 may have the respective axis disposed at an angle from about 1° to about 30° from one another. At the center of the bottom plate 325 there may be no second aperture 365, as shown in FIG. 3F.

The plurality of second apertures 365 and the plurality of third apertures 375 may form alternating staggered rows. The third apertures 375 may be arranged in between at least two of the second apertures 365 of the bottom plate 325. Between each second aperture 365 there may be a third aperture 375, which is evenly spaced between the two second apertures 365. There may also be a number of third apertures 375 positioned around the center of the bottom plate 325 in a hexagonal pattern, such as for example six third apertures, or a number of third apertures 375 forming another geometric shape. There may be no third aperture 375 formed in the center of the bottom plate 325. There may also be no third apertures 375 positioned between the perimeter second apertures 365 which form the vertices of the polygonal pattern of second apertures. Alternatively there may be third apertures 375 located between the perimeter second apertures 365, and there may also be additional third apertures 375 located outwardly from the perimeter second apertures 365 forming the outermost ring of apertures.

Alternatively, the arrangement of the first and second apertures may make any other geometrical pattern, and may be distributed as rings of apertures located concentrically outward from each other and based on a centrally located position on the plate. As one example, and without limiting the scope of the technology, FIG. 3A shows a pattern formed by the apertures that includes concentric hexagonal rings extending outwardly from the center. Each outwardly located ring may have the same number, more, or less apertures than the preceding ring located inwardly. In one example, each concentric ring may have an additional number of apertures based on the geometric shape of each ring. In the example of a six-sided polygon, each ring moving outwardly may have six apertures more than the ring located directly inward, with the first internal ring having six apertures. With a first ring of apertures located nearest to the center of the upper and bottom plates, the upper and bottom plates may have more than two rings, and depending on the geometric pattern of apertures used, may have between about one and about fifty rings of apertures. Alternatively, the plates may have between about two and about forty rings, or up to about thirty rings, about twenty rings, about fifteen rings, about twelve rings, about ten rings, about nine rings, about eight rings, about seven rings, about six rings, etc. or less. In one example, as shown in FIG. 3A, there may be nine hexagonal rings on the exemplary upper plate.

The concentric rings of apertures may also not have one of the concentric rings of apertures, or may have one of the rings of apertures extending outward removed from between other rings, or apertures within one of the rings removed from the pattern. For example with reference to FIG. 3A, where an exemplary nine hexagonal rings are on the plate, the plate may instead have eight rings, but it may be ring four that is removed. In such an example, channels may not be formed where the fourth ring would otherwise be located which may redistribute the gas flow of a fluid being passed through the apertures. The rings may still also have certain apertures removed from the geometric pattern. For example again with reference to FIG. 3A, a tenth hexagonal ring of apertures may be formed on the plate shown as the outermost ring. However, the ring may not include apertures that would form the vertices of the hexagonal pattern, or other apertures within the ring.

The first, second, and third apertures 360, 365, 375 may all be adapted to allow the passage of fluid therethrough. The first and second apertures 360, 365 may have cylindrical shape and may, alternatively, have a varied cross-sectional shape including conical, cylindrical or a combination of multiple shapes. In one example, the first and second apertures 360, 365 may have a diameter from about 0.125 inches to about 0.5 inches, such as about 0.25 inches. The second apertures 365 may alternatively have a diameter the same or greater than first apertures 360.

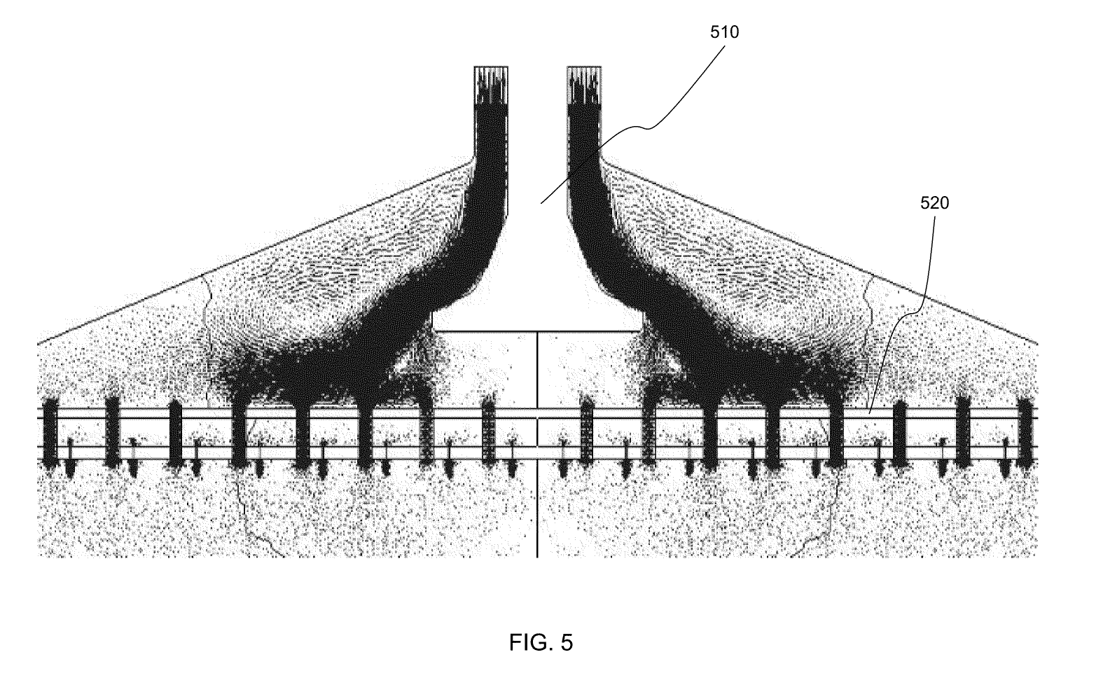

As can be seen in FIG. 5, when all first and second apertures are of the same diameter, the flow of gas through the channels in showerhead 520 may not be uniform. As process gases flow into the processing chamber over the baffle 510, the flow of gas may be such as to preferentially flow a greater volume of gas through certain channels. For example, channels formed by first and second apertures that are located in positions extending outward from the baffle may receive a greater flow of gas than channels formed from first and second apertures located under the baffle, or along the periphery of the showerhead 520. As such, certain of the apertures may be reduced in diameter from certain other apertures in order to redistribute the precursor flow as it is delivered by the baffle 510 to the showerhead 520. The apertures may be selectively reduced in diameter due to their relative position near the baffle, and as such, apertures located near the baffle may be reduced in diameter to reduce the flow of process gas through those apertures. In one example, as shown in FIG. 3A, where nine hexagonal rings of first apertures are located concentrically on the plates, certain rings of apertures may have some or all of the apertures reduced in diameter. For example, ring four may include a subset of first apertures that have a smaller diameter than the first apertures in the other rings. Alternatively, rings two through eight, two through seven, two through six, two through five, two through four, three through seven, three through six, three through five, four through seven, four through six, two and three, three and four, four and five, five and six, etc., or some other combination of rings may have reduced aperture diameters for some or all of the apertures located in those rings.

In another example, a first plurality of apertures 530 may include the first apertures and the second apertures that form fluid channels through showerhead 510. The first plurality of apertures may include a first set of apertures and second set of apertures where the first set of apertures have an aperture diameter that is greater than the aperture diameter of the second set of apertures. A second plurality of apertures 540 may also be included. The first set of apertures 530 may be configured to receive a first fluid to be distributed to the processing region of the semiconductor processing chamber. The second set of apertures 540 may be configured to receive a second fluid to be distributed to the processing region of the semiconductor processing chamber. The showerhead 520 may be configured to maintain the first and second fluids fluidly isolated prior to their distribution to the processing region.

As described previously, the first plurality of apertures may be distributed across the showerhead 520 in concentric rings that comprise a geometric pattern. Each outwardly located concentric ring may include an increasing number of apertures in order to maintain a similar geometric pattern at an increased diameter. At least one of the concentric rings of apertures may include apertures or consist entirely of apertures from the second set of apertures.

Such a combination of aperture locations as described may differ from conventional showerhead designs in several ways. Some conventional showerhead designs may only include two types of apertures, such as certain showerheads having annular apertures surrounding other apertures, which may not have the ability of maintaining fluid isolation between two fluids prior to entry into a deposition region, or may not be able to provide the improved flow characteristics of processing gases. Certain embodiments of the present technology having three types of apertures, for example, may produce improved flow properties between the two sets of first apertures as well as fluid isolation between two processing fluids prior to their being delivered into a processing region of a substrate deposition chamber.

In still another example, one or more rings may have no apertures, a reduced number of apertures, or a reduced size of apertures contained within the ring, or some combination of these in one or more rings. Exemplary showerheads may include formations in which at least one of the concentric rings of apertures includes no aperture in at least one of the locations that would otherwise contain an aperture to maintain the geometric pattern from an inwardly located one of the concentric ring. As one non-limiting example, in a hexagonal pattern having ten rings of apertures, ring four may have no apertures, and ring ten may have apertures with a reduced diameter and also no apertures at what would be the vertices of the hexagon formed by the apertures in the tenth rings.

Disclosed showerheads may include at least six concentric rings of apertures extending outward. At least one of the rings of apertures between the innermost and outermost rings of apertures may consist only of apertures from the second set of apertures. Also exemplary showerheads may include at least five concentric rings of apertures where the first two innermost rings and the last two outermost rings are radially offset from the adjacent ring by a first length. The first length may be about or greater than the radius of an aperture, and may be 2, 3, 4, etc. or more times the radius of an aperture. At least two of the rings may be offset by at least twice the first length without a ring of apertures disposed between the two rings radially. The showerhead may include at least nine concentric rings of apertures, and at least one ring of apertures of rings three through six of outwardly numbered rings may include or consist entirely of apertures from the second set of apertures. In disclosed embodiments at least two rings of apertures of rings three through six of outwardly numbered rings may include or consist of apertures from the second set of apertures. Many additional variations encompassed by the technology may be contemplated for redistributing precursor flow through the upper and bottom plate. As shown in FIG. 5, the first plurality of apertures may be defined in a first plate, and the second plurality of apertures may be defined in a second plate. The plates may be coupled with one another such that a volume is defined between the first and second plates as shown. The showerhead may be configured to receive the second fluid into the volume defined between the first and second plates, and further be configured to prevent the second fluid from flowing up through the first plate. In this way, the second fluid may only have fluid access from the showerhead through the second plurality of apertures.

The aperture sizes of the reduced diameter apertures may be related to the other apertures as a percentage of aperture size. The apertures with reduced diameter may range from 100% to 0% of the diameter of the other apertures where 100% refers to an aperture of the same size, and 0% refers to the absence of an aperture. For example, and utilizing the above referenced ten ring pattern where ring four has no apertures, rings one through three, and rings five through nine, may have aperture diameters of a certain size that may be, in one embodiment, about 0.25 inches diameter. Ring four may have apertures that range from about 0% the diameter of the other apertures to about 50% diameter. Thus, for the exemplary 0.25 inches diameter apertures, the apertures of ring four would range from about 0 inches, or non-existing, to about 0.125 inches diameter. Alternatively, the apertures in ring four may have a diameter that ranges from about 0% the diameter to about 40% the diameter, or therein between. Ring ten may, for example, have an equivalent number of apertures as row nine, eight, seven, etc., or some number of apertures therein between, and thus may have fewer apertures than would the otherwise located tenth hexagonal ring of the ascending pattern. Additionally, the apertures in row ten may have a diameter that is at or between about 40% and about 100% of the diameter of the other apertures in other rings.

Other exemplary structures may include nine rings, for example, and rings two through five may have aperture diameters between about 50% and about 100% of the diameter of the other apertures. Alternatively, the apertures in rings two through five may have aperture diameters that differ between those rings, such as, for example, ring two may include apertures having a diameter of between about 90% and about 100% of the aperture diameters of the other non-reduced apertures. Also, ring three may have apertures with a diameter between about 85% and about 95% of the diameter of the non-reduced apertures, and so on. Many other variations encompassed by the technology will become apparent to one of skill in the art from these exemplary showerhead designs.

The inventors have also unexpectedly realized that changes in the aperture diameters may have correlated effects on deposition. For example, and without wishing to be bound by any particular theory, by reducing the diameter of apertures located in the natural fluid flow path directly outward from the baffle, an improved flow characteristic of the precursor gas may be achieved. The improved flow characteristic may improve residence time of the precursor gas in the deposition space, which may allow for an overall increase of interactions between precursor gases. The increase in interactions may proportionately increase the amount of deposited materials. In some instances, the amount of deposited material for an equivalent amount of time may increase by more than about 20%. Such improved depositions may reduce the time needed for film deposition, etching, etc., such that overall process flow for substrate fabrication may be increased.

The third apertures 375 may have an hourglass shape, as seen in FIG. 3G. The third apertures may have a profile or define a shape of a first cylindrical section 376 (nozzle) having a first diameter from about 0.2 to about 0.3 inches, such as about 0.25 inches. The first cylindrical section 376 may have an inlet at one end. The first cylindrical section 376 may have a height of about 0.1 to about 0.12 inches, such as about 0.11 inches. A second cylindrical section 378 (throat) having a second diameter less than the first diameter may be coupled with the first cylindrical section 376 by a transitional section 377. The second diameter may be from about 0.01 to about 0.03 inches, such as about 0.016 inches, or about a ratio of first diameter to second diameter from about 30:1 to about 6:1, such as about 16:1. The second cylindrical section 378 may have a height of about 0.01 to about 0.02 inches, such as about 0.017 inches. The transition section 377 may taper, such as at an angle of about 120°, from the first section 376 and first diameter to the second section 378 and second diameter. The transition section 377 may have a height of about 0.1 to about 0.12 inches, such as about 0.11 inches. A third section 374 (diffuser) may be coupled to the second cylindrical section 378. The third section 374 may have a conical shape expanding from the second cylindrical section 378 to an outlet with a height from about 0.2 inches to about 0.3 inches, such as about 0.25 inches, and may have an outlet diameter greater than the second diameter and less than the first diameter. The third diameter may be from about 0.05 inches to about 0.08 inches, such as about 0.06 inches. Alternatively, each of the plurality of third apertures may have a cylindrical shape and have a diameter the same or greater than the plurality of first apertures 360.

Referring to FIGS. 3J and 3M, the annular body 340 may have a number of fluid delivery channels 380 formed radially inward of the cooling channels 356, 357 and into the upper recess 303. The fluid delivery channels 380 may be fluidly coupled to a conduit 372. The fluid delivery channels 380 may also be fluidly coupled with a plurality of fluid passages 381 which may be formed into the upper recess 303 radially inward of the fluid delivery channels 380.

As stated previously, the gas distribution assembly 300 generally consists of the annular body 340, the upper plate 320, and the bottom plate 325. The upper plate 320 may be positioned within the upper recess 303 with the raised cylindrical bodies 307 facing toward the bottom surface 310 of the annular body 340, as shown in FIG. 3L. The bottom plate 325 may then be positioned on the seat 304 with and rotatably oriented so that the axes of the first and second apertures 360, 365 may be aligned, as shown in FIG. 3L. The upper plate 320 may be sealingly coupled to the bottom plate 325 to fluidly isolate the first and second apertures 360, 365 from the third apertures 375. For example, the upper plate 320 may be brazed to the bottom plate 325 such that a seal is created between a surface of the raised cylindrical bodies 307 and a surface of the bottom plate 325. The upper plate 320 and bottom plate 325 may then be E-beam welded to the annular body 340. The upper plate 320 may be E-beam welded such that a seal is created between an outer edge 311 of the circular body and an inner edge 312 of the upper recess 303. The bottom plate 325 may be E-beam welded such that a seal is created between an outer edge 313 of the circular body and the inner annular wall 301. Fluid may flow through the first and second apertures 360, 365 along flow path F₁. Fluid may also flow separately through the conduit 372, into the fluid delivery channels 380, through the fluid passages 381, through the gaps 395, and through the third apertures 375 along flow path F₂. Having fluid flow along two separate flow paths F₁, F₂ may ensure that reaction of the fluids occurs after exiting the gas distribution assembly 300, which may help to prevent buildup of materials within the gas distribution assembly 300. In one embodiment, the surfaces of the gas distribution assembly 300 may be electro-polished.

Referring to FIGS. 4A-4H, one embodiment of a gas distribution assembly 400, or showerhead, is provided including a first or upper manifold 410 and a second or bottom manifold 415, and the top of the second manifold 415 may be configured to be coupled to the bottom of the first manifold 410. In usage, the orientation of the showerhead 400 to the substrate may be done in such a way that the axis of any apertures formed in the showerhead may be perpendicular or substantially perpendicular to the substrate plane.

FIG. 4A illustrates a perspective view of the top of the showerhead including the first manifold 410, and FIG. 4B illustrates a perspective view of the bottom of the showerhead including the second manifold 415. FIG. 4C illustrates a bottom plan view of the second manifold. FIG. 4D illustrates a side view of the showerhead along line 4D of FIG. 4C. FIG. 4D′ is a schematic side view of one embodiment of the first aperture. FIG. 4E is a schematic side view of the circular plate of the second manifold. FIG. 4F is a schematic side view of one embodiment of the third aperture of FIG. 4E. FIG. 4G is a schematic side view of one embodiment of the second and third apertures of FIG. 4E. FIG. 4H is a top view of the first manifold and does not show the circular plate with the apertures. FIG. 4I is a top view of the bottom manifold having the circular plate with aperture pattern described herein and does not show the circular plate.

First manifold 410 may include an inner circular plate 420 disposed in an outer rim 440. A lateral conduit 450 may be formed in the outer rim 440.

Referring to FIGS. 4A and 4B, the inner circular plate 420 has a plurality of first apertures 460 formed in a pattern portion 470 and the apertures may be configured for passage of a fluid therethrough. The pattern portion 470 may comprise an array of staggered rows from 15 to 25 rows, for example, 19 rows. Each row may have, along the y-axis, from 2 to 20 apertures, such as from 4 to 17 apertures, with each row being spaced between about 0.4 and about 0.7 inches apart, for example, about 0.54 inches apart. Each aperture in a row may be displaced along the x-axis from a prior aperture between about 0.4 and about 0.8 inches, such as about 0.63 inches, from each respective diameter. The apertures may be staggered along the x-axis from an aperture in another row by between about 0.2 and about 0.4 inches, such as about 0.31 inches, from each respective diameter. The apertures may be equally spaced from one another in each TOW.

Each first aperture 460 may have a conical inlet portion tapering to a first cylindrical portion. In one example, the apertures 460 may have an inlet diameter from about 0.2 inches to about 0.5 inches, such as about 0.35 inches tapering at about 90° to a first cylindrical portion diameter from about 0.125 to about 0.4 inches, for example, about 0.25 inches. The apertures 460 may extend through the circular plate to provide a passage for fluids therethrough. The combined height of the first aperture may be from about 0.05 to about 0.15 inches and the conical inlet portion tapering to a first cylindrical portion may have equal heights. The patterned portion of the circular plate may vary based on the size of the circular plate, and may be at a diameter from about 0.5 to about 6 inches of the circular plate having a diameter of about 14 inches.

Referring to FIGS. 4B, 4E, 4F, 4G, 4H and 4I, the inner circular plate 425 may have a plurality of second apertures 465 formed in a pattern portion 485 and the second apertures may be configured for passage of a fluid therethrough. The inner circular plate also may have a plurality of third apertures 475 formed in the pattern portion 485 and the third apertures may be configured to pass a gas introduced into the showerhead by a fluid passage into a processing chamber in which the showerhead is positioned. The circular plate may have a thickness from about 0.1 to about 0.2 inches, such as about 0.15 inches.

Referring to FIG. 4H, the first manifold 415 may be encircled by a plurality of fluid delivery channels 480 formed in the rim 440 which may be in fluid communication with the third apertures 475 and may be in fluid communication with a second fluid source entry 490 configured to allow passage of a fluid from an external source into the showerhead. The second manifold 415 may include an inner circular plate 425 disposed within an outer rim 445.

The plurality of second apertures 465 of the second manifold may be aligned with the plurality of first apertures. The plurality of first apertures 460 and the plurality of second apertures 465 may have the respective axis parallel or substantially parallel to each other. Alternatively, the plurality of first apertures 460 and the plurality of second apertures 465 may have the respective axis disposed at a angle from about 1° to about 30° from one another.

The pattern portion 485 may comprise an array of staggered rows from 15 to 25 rows, for example, 19 rows. Each row may have, along the y-axis, from about 2 to about 20 apertures, such as from about 4 to about 17 apertures, with each row being spaced between about 0.4 and about 0.7 inches apart, for example, about 0.54 inches apart. Each aperture in a row may be displaced along the x-axis from a prior aperture between about 0.4 and about 0.8 inches, such as about 0.63 inches, from each respective diameter. The apertures may be staggered along the x-axis from an aperture in another row by between about 0.2 and about 0.4 inches, such as about 0.31 inches, from each respective diameter. The apertures may be equally spaced from one another in each row.

Each second aperture 465 may have a second cylindrical portion coupled to a conical outlet portion expanding to an outset. In one example, the apertures 465 may have a second cylindrical portion diameter from about 0.125 to about 0.4 inches, for example, about 0.25 inches and an outlet diameter from about 0.2 inches to about 0.5 inches, such as about 0.40 inches tapering at about 40° from the second cylindrical portion. The apertures 465 may have a diameter the same or greater than apertures 460. The apertures 465 may extend through the circular plate to provide a passage for fluids therethrough. The combined height of the first aperture may be from about 0.05 to about 0.5 inches, for example, about 0.35 inches. The patterned portion of the circular plate may vary based on the size of the circular plate, and may be at a diameter from about 0.5 to about 6 inches of the circular plate having a diameter of about 14 inches.

The pattern portion 485 may comprise the plurality of third apertures in an array of staggered rows from about 30 to about 45 rows, for example, about 37 rows. Each row may have, along the y-axis, from about 2 to about 30 third apertures, such as from about 3 to about 17 apertures, with each row being spaced between about 0.2 and about 0.35 inches apart, for example, about 0.31 inches apart. Every other row may be disposed along the same x-axis row as the second apertures, and the third apertures may be in an alternating order with the second apertures along the x-axis. Each third aperture in a row may be displaced along the x-axis from a prior third aperture between about 0.4 and about 0.8 inches, such as about 0.31 inches, from each respective diameter for a row with only third apertures. Each third aperture in a row may be displaced along the x-axis from a prior second aperture between about 0.4 and about 0.8 inches, such as about 0.31 inches, from each respective diameter for a row with only third apertures. The third apertures may be staggered along the x-axis from a third aperture in another row by between about 0.1 and about 0.2 inches, such as about 0.16 inches, from each respective diameter. The apertures may be equally spaced from one another in each row.

Referring to FIG. 4G, the third apertures may have a profile or define a shape of a first cylindrical portion 476 (nozzle) having a first diameter from about 0.2 to about 0.3 inches, such as about 0.25 inches. The first cylindrical portion may have an inlet at one end. The first cylindrical portion may have a height of about 0.1 to about 0.16 inches, such as about 0.14 inches. A second cylindrical portion 478 having a second diameter less than the first diameter may be coupled with the first cylindrical portion 476 by a transitional section 477. The second diameter may be from about 0.04 to about 0.07 inches, such as about 0.06 inches, or about a ratio of first diameter to second diameter from about 7.5:1 to about 3:1, such as about 4:1. The second cylindrical portion may have a height of about 0.01 to about 0.1 inches, such as about 0.05 inches. The transition portion 477 tapers, such as at an angle of about 40°, from the first section and first diameter to the second section and first prime diameter of from greater than about 0.07 to about 0.1, for example, about 0.08 inches. The first prime diameter may be greater than the second diameter.

A third cylindrical portion 444 (throat) may be coupled with the second cylindrical portion 478 and may have a third diameter from about 0.01 to about 0.03 inches, such as about 0.016 inches, or about a ratio of first diameter to third diameter from about 30:1 to about 6:1, such as about 16:1. The third cylindrical portion may have a height of about 0.01 to about 0.03 inches, such as about 0.025 inches. A fourth cylindrical portion 479 (diffuser) may be coupled to the third cylindrical portion 444. The fourth cylindrical portion may have a diameter similar to the second cylindrical portion 478 having a fourth diameter less than the first diameter. The fourth diameter may be from about 0.04 to about 0.07 inches, such as about 0.06 inches, or about a ratio of first diameter to second diameter from about 7.5:1 to about 3:1, such as about 4:1. The fourth cylindrical portion may have a height of about 0.01 to about 0.5 inches, such as about 0.025 inches.

As previously described, alternative arrangements of the first and second apertures may make any other geometrical pattern, and may be distributed as rings of apertures located concentrically outward from each other and based on a centrally located position on the plate. Each outwardly located ring may have the same number, more, or less apertures than the preceding ring located inwardly. In one example, each concentric ring may have an additional number of apertures based on the geometric shape of each ring. In the example of a six-sided polygon, each ring moving outwardly may have six apertures more than the ring located directly inward, with the first internal ring have six apertures. With a first ring of apertures located nearest to the center of the upper and lower plates, the upper and bottom plates may have more than two rings, and depending on the geometric pattern of apertures used, may have between about one and about fifty rings of apertures. Alternatively, the plates may have between about two and about forty rings, or up to about thirty rings, about twenty rings, about fifteen rings, bout twelve rings, about ten rings, about nine rings, about eight rings, about seven rings, about six rings, etc. or less.

In still another example, one or more rings may have no apertures, a reduced number of apertures, or a reduced size of apertures contained within one or more rings, or some combination of these in one or more rings. The aperture sizes of the reduced diameter apertures may be related to the other apertures as a percentage of aperture size. The apertures with reduced diameter may range from 100% to 0% of the diameter of the other apertures where 100% refers to an aperture of the same size, and 0% refers to the absence of an aperture. As one non-limiting example, in a hexagonal pattern having nine rings of apertures, rings three and four may have apertures with diameters between about 50% and about 100% the diameter of the non-reduced apertures, and alternatively may be between about 75% and about 95%, or between about 88% and about 92%. Many additional variations encompassed by the technology may be contemplated for redistributing precursor flow through the upper and bottom plate.

Referring to FIGS. 4E-4I, a first fluid may flow, F1, such as a processing gas, through the showerhead via a first aperture 460 in the upper manifold and the second aperture 465 in the bottom manifold before entry into a processing region. The second fluid may flow, F2, such as a precursor, to the processing region by flowing through a channel 490 to a gas distribution channel 480 to an inner region 495 between the upper manifold and the lower manifold that may be an isolated flow path surrounding the first and second apertures that exits through third apertures 475. Both the first fluid and the second fluid may be fluidly isolated from one another in the showerhead until delivery into a processing region.

Methods are also described for flowing precursor gases through a showerhead such as those described throughout the disclosure. A first precursor may be flowed through a first plurality of apertures in the showerhead and may be delivered into a processing region of a semiconductor processing chamber. The first plurality of apertures may include a first set of apertures and a second set of apertures where the first set of apertures have an aperture diameter that may be greater than the aperture diameter of the second set of apertures. The first precursor may be delivered through the first plurality of apertures such that a substantially equivalent amount of the first precursor is delivered through each of the plurality of first apertures. The amount of the first precursor may be identical in disclosed embodiments, and may be within about 1% or more of the amount of precursor delivered through any other of the first apertures. For example, the amount of first precursor that may be delivered through any two apertures of the first plurality of apertures may be within about 5% or less of each other, about 10% or less of each other, about 20% or less of each other, about 30% or less of each other, etc. or more.

The methods may also include flowing a second precursor through a second plurality of apertures in the showerhead that may be delivered into the processing region of the semiconductor processing chamber. The second plurality of apertures may be maintained fluidly isolated from the first plurality of apertures such that the first and second precursor are maintained fluidly isolated until they are delivered into the processing region. For example, the first plurality of apertures may be defined within a first plate and the second plurality of apertures may be defined in a second plate. The plates may be coupled such that a volume is formed between the plates into which the second precursor is flowed.

### Example

Comparative examples were made between the deposition characteristics achieved using two showerhead configurations. The first showerhead included ten rings of apertures, and every aperture was of a similar diameter. The second showerhead included nine rings of apertures, and rings three and four counted from the center included apertures of a reduced diameter as compared to the other apertures of the other rings. Processing and precursor gases were flowed through the showerheads and allowed to react to deposit a material on a 300 mm silicon semiconductor wafer. The wafer was then analyzed along the surface to determine the thickness of the deposited liner at all points across the wafer.

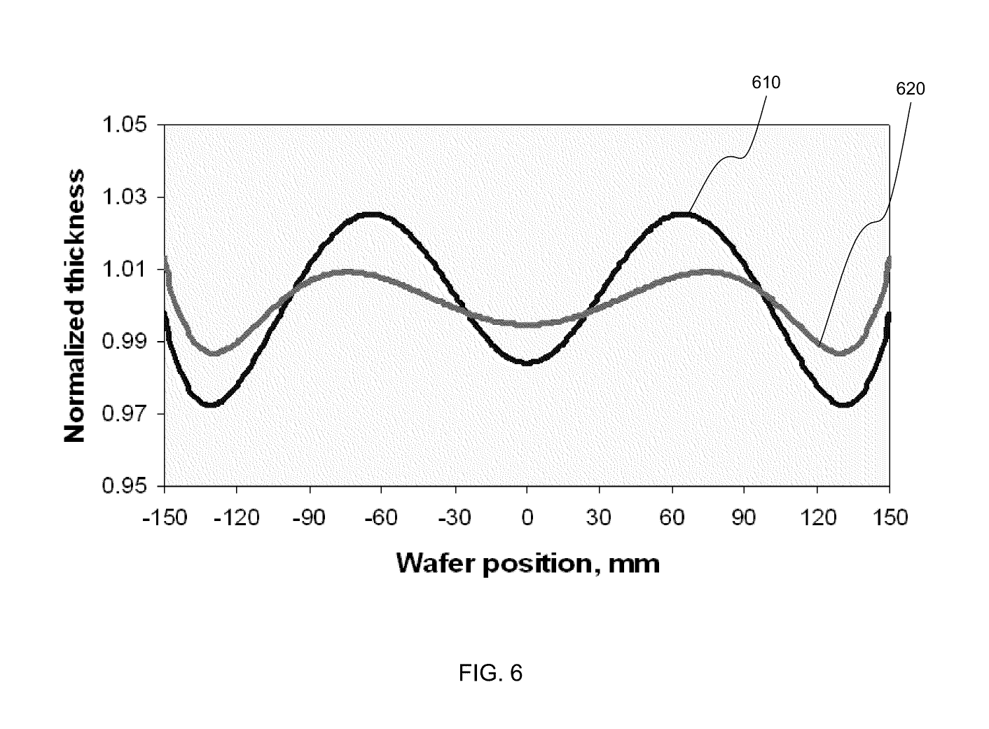

FIG. 6 shows a graph of deposition thickness as a function of position on a wafer for the tested showerheads. Line 610 shows the deposition profile across the wafer for the showerhead including ten rings of apertures having similar diameters. As seen in the graph, the thickness varies by a large percentage across the wafer. Nearer to the edges of the wafer, and nearer to the center of the wafer, the deposited material thickness is much less than at the positions at about 60 mm from the center of the wafer. This region correlates to middle rings of apertures that are in a direct flow path from the baffle, as can be seen in FIG. 5.

Line 620 shows the deposition profile across the wafer for the showerhead including nine rows with rows three and four having apertures of reduced size. As can be seen, a more uniform deposition profile was achieved with this showerhead design, and non-uniformity across the wafer was reduced to less than about 1.5%. Additionally, the showerhead including apertures of reduced diameter produced a thicker film than the other showerhead, and the deposited material was more than about 20% greater thickness, which may have been a result of increased residence times of the processing gases.

In the preceding description, for the purposes of explanation, numerous details have been set forth in order to provide an understanding of various embodiments of the present invention. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the disclosed embodiments. Additionally, a number of well-known processes and elements have not been described in order to avoid unnecessarily obscuring the present invention. Accordingly, the above description should not be taken as limiting the scope of the invention.

It is noted that individual embodiments may be described as a process which is depicted as a flowchart, a flow diagram, or a block diagram. Although a flowchart may describe the method as a sequential process, many of the operations may be performed in parallel or concurrently. In addition, the order of the operations may be rearranged. A process may be terminated when its operations are completed, but could have additional steps not discussed or included in a figure. Furthermore, not all operations in any particularly described process may occur in all embodiments. A process may correspond to a method, a function, a procedure, a subroutine, a subprogram, etc. When a process corresponds to a function, its termination corresponds to a return of the function to the calling function or the main function.

Where a range of values is provided, it is understood that each intervening value between the upper and lower limits of that range is also specifically disclosed, to the smallest fraction of the unit or value of the lower limit, unless the context clearly dictates otherwise. Any encompassed range between any stated value or intervening value in a stated range and any other stated or intervening value in that stated range is disclosed. The upper and lower limits of those smaller ranges may independently be included or excluded in the range, and each range where either, neither, or both limits are included in the smaller range is also disclosed and encompassed within the technology, subject to any specifically excluded limit, value, or encompassed range in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a dielectric material” includes a plurality of such materials, and reference to “the process” includes reference to one or more processes and equivalents thereof known to those skilled in the art, and so forth.

Also, the words “comprise”, “comprising”, “contain”, “containing”, “include”, “including”, and “includes”, when used in this specification and in the following claims, are intended to specify the presence of stated features, integers, components, or steps, but they do not preclude the presence or addition of one or more other features, integers, components, steps, acts, or groups.

What is claimed is:

1. A showerhead comprising:
a first plurality of apertures configured to receive a first fluid to be distributed to a processing region of a semiconductor substrate processing chamber, wherein the first plurality of apertures includes a first set of apertures and a second set of apertures, and wherein the first set of apertures have an aperture diameter that is greater than the aperture diameter of the second set of apertures; and
a second plurality of apertures configured to receive a second fluid to be distributed to the processing region of the semiconductor substrate processing chamber, wherein the showerhead is configured to maintain the first and second fluids fluidly isolated prior to their distribution to the processing region.

2. The showerhead of claim 1, wherein:
the first plurality of apertures are distributed in the showerhead in concentric rings, and the rings comprise a geometric pattern,
each outwardly located concentric ring comprises an increasing number of apertures to maintain a similar geometric pattern at an increased diameter, and
at least one of the concentric rings of apertures comprises apertures from the second set of apertures.

3. The showerhead of claim 2, wherein at least one of the concentric rings of apertures includes no aperture in at least one of the locations that would otherwise contain an aperture to maintain the geometric pattern from an inwardly located one of the concentric rings.

4. The showerhead of claim 2, wherein the showerhead includes at least 6 concentric rings of apertures, wherein at least one of the rings of apertures between the innermost and outermost rings of apertures consists of apertures from the second set of apertures.

5. The showerhead of claim 2, wherein the showerhead includes at least 5 concentric rings of apertures, wherein the first two innermost rings and the last two outermost rings are radially offset from the adjacent ring by a first length.

6. The showerhead of claim 5, wherein at least two of the rings are offset by at least twice the first length without a ring of apertures disposed between the two rings radially.

7. The showerhead of claim 2, wherein the showerhead includes at least 9 concentric rings of apertures, wherein at least one ring of apertures of rings three through six of outwardly numbered rings comprises apertures from the second set of apertures.

8. The showerhead of claim 7, wherein at least two rings of apertures of rings three through six of outwardly numbered rings comprises apertures from the second set of apertures.

9. The showerhead of claim 1, wherein the first plurality of apertures are defined in a first plate, and wherein the second plurality of apertures are defined in a second plate.

10. The showerhead of claim 9, wherein the first and second plates are coupled with one another such that a volume is defined between the first and second plates.

11. The showerhead of claim 10, wherein the showerhead is configured to receive the second fluid into the volume defined between the first and second plates.

12. The showerhead of claim 11, wherein the first and second plates are coupled with one another to prevent access by the second fluid through the first plate.

13. A gas distribution assembly, comprising:
an annular body comprising:
an inner annular wall located at an inner diameter, an outer annular wall located at an outer diameter, an upper surface, and a bottom surface;
an upper recess formed in the upper surface;
a lip formed radially outward of the inner wall, and located toward the bottom surface;
a seat formed in the inner annular wall and located toward the bottom surface;
an upper plate coupled with the upper recess of the annular body, comprising a plurality of first apertures formed therein; and
a bottom plate coupled with the seat formed in the inner annular wall of the annular body, comprising:
a plurality of second apertures formed therein, wherein the second apertures align with the first apertures;
a plurality of third apertures formed therein and located between the second apertures;
wherein the first and second apertures are aligned and form a pattern of concentric geometric shapes of first and second apertures on the upper and lower plates, and further wherein a first subset of the first and second apertures comprise an aperture diameter that is less than the aperture diameter of a second subset of the first and second apertures.

14. The gas distribution assembly of claim 13, wherein the bottom plate is sealingly coupled with the upper plate such that the aligned first and second apertures are fluidly isolated from the third apertures.

15. The gas distribution assembly of claim 13, wherein the concentric geometric shapes of apertures on the bottom plate comprise at least two rings of apertures, the rings of outwardly increasing diameter, and the apertures forming each ring are of the same aperture diameter as the other apertures contained in that ring, and wherein at least one of the rings of first and second apertures comprises aperture diameters that are different than the aperture diameters of the first and second apertures located in a second ring.

16. The gas distribution assembly of claim 13, wherein the upper plate and bottom plate are joined together forming a seal around each pair of aligned first and second apertures, wherein the upper plate is welded to the annular body creating a seal between an outer edge of the upper plate and an inner edge of the upper recess, and wherein the bottom plate is welded to the annular body such that a seal is created between an outer edge of the bottom plate and the inner annular wall.

17. The gas distribution assembly of claim 16, wherein the annular body further comprises:
a first sealing channel formed on the upper surface of the annular body radially outward of the upper recess; and
a second sealing channel formed on the bottom surface of the annular body radially outward of the upper recess.

18. The gas distribution assembly of claim 17, wherein the annular body further comprises:
fluid delivery channels formed into the upper recess radially inward of the first cooling channel;
fluid passages formed into the upper recess radially inward of the fluid delivery channels, the fluid passages fluidly coupled to the fluid delivery channels; and
a conduit formed through the outer annular wall of the annular body and fluidly coupled to the fluid delivery channels that forms a flow path from an inlet of the conduit to an outlet of the plurality of third apertures.

19. The gas distribution system of claim 13, wherein the annular body further comprises:
a heater recess formed in the bottom surface of the annular body radially outward of the second cooling channel.

20. The gas distribution assembly of claim 13, wherein the plurality of third apertures have an hourglass shape.
